(19) United States
(12) Patent Application Publication
(10) Pub. No.: US 2004/0117708 A1
(43) Pub. Date: Jun. 17, 2004

(54) Pre-announce signaling for interconnect built-in self test

(76) Inventors: David G. Ellis, Tualatin, OR (US); Bruce Querbach, Orangevale, CA (US); Jay J. Nejedlo, Wilsonville, OR (US); Amjad Khan, Folsom, CA (US); Sean R. Babcock, Portland, OR (US); Eric S. Gayles, Folsom, CA (US); Eshwar Gollapudi, Folsom, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/404,949

(22) Filed: Mar. 31, 2003

Related U.S. Application Data
(63) Continuation-in-part of application No. 10/319,517, filed on Dec. 16, 2002.

(51) Int. Cl. G01R 31/28

(52) U.S. Cl. 714/733

(57) ABSTRACT

An integrated circuit (IC) component of a computer system, intended for use as part of a production version of the system, is provided with a built-in test unit and core function circuitry that are coupled to transfer information over the same I/O buffer circuitry of the component. The test unit is to transfer test information during a test session and to recognize announcement of the test session via an assertion and a deassertion, for predetermined time intervals, of an inter-component signal.

This application is a continuation in part of U.S. application Ser. No. 10/319,517 filed Dec. 16, 2002 entitled “Testing Methodology and Apparatus for Interconnects” (pending) (P13588)

### RELATED PATENT APPLICATIONS

U.S. application Ser. No. _ _ _ _ _ _ filed Mar. 20, 2003 entitled, “A Reusable, Built-In Self Test Methodology for Computer Systems” (pending) (P16154)

### BACKGROUND

The invention is related to methodologies for testing computer systems and their integrated circuit (IC) components, during and after manufacture, to determine whether their electrical specifications have been met as well as that they have been assembled correctly.

Industry trends for high performance, computer systems, such as those that use a Pentium processor and an associated chipset by Intel Corp., Santa Clara, Calif., are towards faster product cycle times (time to market) with sustained high quality. At the same time, component to component bus speeds are increasing beyond several hundred MHz, and in some cases, as in high speed serial interfaces, are in the GHz range. Also, printed wiring board densities are increasing, to meet the need for greater performance. These demands are rendering conventional testing techniques such as oscilloscope and logic analyzer probing less reliable, or even impossible, on high speed interfaces, both in the high volume manufacturing setting as well as earlier in the electrical validation and verification setting.

At the board and platform level, the system has its primary components, including the processor, system chipset, and memory, installed on a motherboard. In that stage of manufacturing, transaction-based tests have been used, in a board or platform high volume manufacturing setting, to verify a wide range of storage and logic functions of the system. Such tests evaluate whether the memory subsystem and the I/O subsystem work according to their electrical specifications. The test is performed by the processor executing a special test routine, during or after booting an operating system (OS) program, that causes test patterns that are part of the test routine to be written to and then read from addresses that span the computer system. However, faults of a high frequency type (such as due to cross talk between adjacent signal lines and inter-symbol interference (ISI) due to transmission line effects) cannot be detected or isolated using such techniques, due to the coarse test granularity and high instruction overhead associated with running an OS-based test program.

Another type of computer system test calls for the processor to execute firmware/software that operates at a lower level than an OS-based program, prior to booting the operating system. These include basic I/O system (BIOS) and extended firmware interface (EFI) programs. Although these types of tests provide relatively low-level, and hence more accurate, control of component functionality and interconnect buses, system interactions cannot be stressed to their bandwidth specifications in such tests. In addition, the ability of BIOS/EFI tests to isolate a fault with sufficient granularity is also limited.

Finally, there is a low level technique known as boundary scan testing (or the Joint Test Access Group, JTAG, protocol) which calls for on-chip circuitry used to control individual bits transmitted between components. Once again, however, there is no provision for testing high frequency faults. For example, a boundary scan test may detect “opens” and “shorts” while running at a 10 MHz clock, whereas normal signaling speed on the interconnect will be in the GHz range.

The related applications identified above, which are assigned to the same assignee as that of this application, namely Intel Corp., describe an interconnect built-in self test (IBIST) methodology. That solution addresses some of the shortcomings of conventional computer system testing, e.g. isolating high-speed faults of chip to chip interconnects. In such testing, communication between the IBIST cells of two IC components may need some form of synchronization, so that a slave cell “knows” when to start evaluating or how to latch a sequence of information elements that have been transmitted by a master cell. This can be done using a bus control signal (e.g. an address strobe or ADS#; data parity or DP#; data ready or DRDY#), to signal when a sequence of information elements is about to be launched by a master cell. For example, during normal bus operation between the two IC components (when agents are communicating according to a bus protocol and at nominal bus speed), each time ADS# is asserted, a new address is being transmitted on the address lines of the bus. Accordingly, an IBIST cell may be designed to cause the assertion of ADS# as soon as it is about to launch a test pattern.

### BRIEF DESCRIPTION OF THE DRAWINGS

The invention is illustrated by way of example and not by way of limitation in the figures of the accompanying drawings in which like references indicate similar elements. It should be noted that references to “an” embodiment of the invention in this disclosure are not necessarily to the same embodiment, and they mean at least one.

FIG. 1 is a block diagram of an example computer system that has been enhanced with BIST units in its primary IC components.

FIG. 2 is a block diagram that illustrates, in more detail, a part of the computer system in which a pair of BIST-enhanced, primary IC components are connected via a parallel bus.

FIG. 3 is a conceptual timing diagram of a pre-announce signaling process, for common clock signals.

FIG. 4 is a conceptual timing diagram of a pre-announce signaling process, for data pins.

FIG. 5 is a conceptual timing diagram of a pre-announce signaling process, for address pins.

FIG. 6 is a logic block diagram of part of an IBIST cell with pre-announce signaling capability.

### DETAILED DESCRIPTION

A problem has been discovered in the case where the IBIST test methodology is entirely independent of the bus protocol, e.g. test information may be launched and then captured at essentially any instant following the initial assertion of a bus control signal. This creates a problem for the slave cell in that it cannot always know at what moment the test session starts. This may also be true if a clocking signal other than the asserted bus control signal, and which may not be synchronized to that control signal, is to be used by the slave cell to capture the information elements during the test session.

A solution may be to still use the asserted, bus control signal, but also deassert the signal for a predetermined time interval. This combination of assertion and deassertion for predetermined time intervals (of which both the slave and master cells have knowledge) may be used to announce or coordinate the start of a test session among two or more IBIST cells, in a very efficient manner. Before discussing the details and examples of this so-called “pre-announce” capability of the BIST unit, a description of a computer system of which a BIST-enhanced component is to be a part will be given.

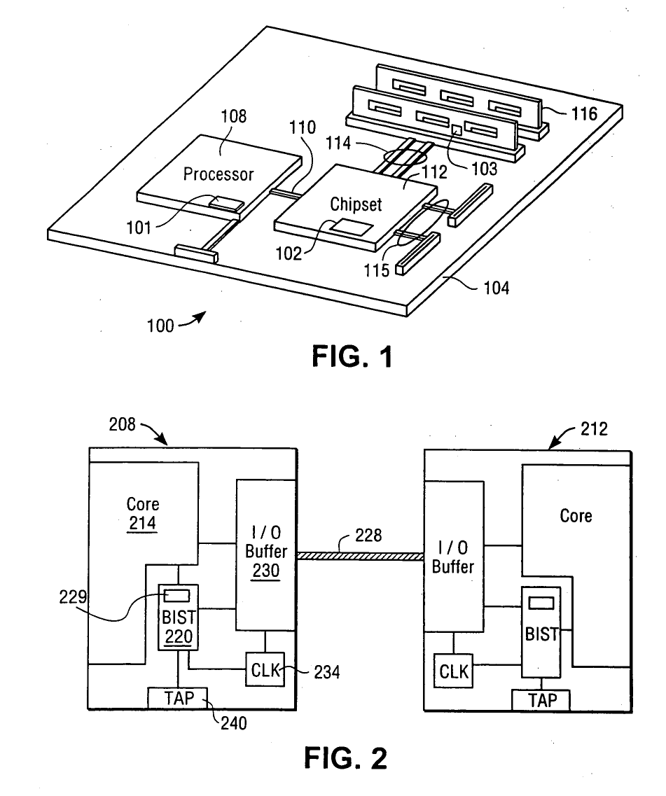

FIG. 1 is a block diagram of an example computer system 100 enhanced with BIST units 101, 102, and 103. The BIST units 101-103 are associated with their respective core function circuitry (not shown in FIG. 1) and are located in the primary IC components of the system 100. The primary IC components in this case include a processor 108 (e.g. a Pentium processor by Intel Corp.), a system interface or chipset 112, and memory subsystem hardware 116. The BIST units 101-103 may be integrated into a primary IC component package or module, such as a separate chip within a multi-chip module. A BIST unit may alternatively be located on-chip with the processor or chipset core circuitry. The BIST unit may be implemented as a state machine with configuration registers that are accessible from outside its component. These components are to be used as part of a production version of the system 100, a high volume manufacturing (HVM) specimen.

The primary IC components of the system 100 communicate with each other using interconnects. In this case, the interconnects include a processor bus 110 and memory interface bus 114 formed in a carrier substrate 104. Both of those buses may be parallel buses. For example, the processor 108, chipset 112, and bus 110 may be designed for a Front Side Bus protocol by Intel Corp., to run at nominal bus speeds of over five hundred (500) MHz bus clock frequency.

In addition to the parallel buses, the system 100 also has a high-speed serial interface 115, which can be tested via the BIST unit 102 of the chipset 112. In this case, the serial interface 115 is also formed in the same carrier substrate 104 (e.g. a motherboard; a daughter card), and is part of the I/O subsystem of the computer system 100. The chipset 112 and serial interface 115 may be designed according to the Peripheral Component Interconnect (PCI) Express standard described in PCI Express Specification 1.0 and PCI Express Card Electro Mechanical Specification which are available from the PCI Special Interest Group, Portland, Oreg. Of course, primary IC components and computer system architectures other than those depicted in FIG. 1 can also be enhanced with BIST units.

FIG. 2 is a block diagram that illustrates, in more detail, a part of a BIST-enhanced computer system 200. The following description of the component 208 also applies to another component 212, unless otherwise noted. In the component 208, both the core function circuitry 214 and the BIST unit 220 are coupled to control an interconnect bus 228 through the same I/O buffer circuitry 230. During normal operation, the core function circuitry 214 may act as a bus agent and communicates with other bus agents at a nominal bus speed, set by or regulated by clock circuitry 234. The I/O buffer circuitry 230 receives and responds to bus control and other information elements (e.g. address; data; control) from the core function circuitry 214 (which may be that of a processor, chipset, or memory subsystem hardware), at the nominal bus speed. However, upon system or component power-up, and during special test modes, the BIST unit 220 may be requested to take full control of the bus 228, through the I/O buffer circuitry 230. The BIST unit 220 thus uses the same on-chip, logic-to-transmission-line signal interface as the core function circuitry 214, namely the I/O buffer circuitry 230. In addition, information elements provided by the BIST unit 220 may be launched and captured at the same, nominal bus speed. The BIST unit 220 thus experiences the same signal paths and timing delays as the core function circuitry 214 when launching and capturing information elements on the bus 228. This yields a more effective test methodology, particularly for isolating faults due to high speed operation, including faults such as intersymbol interference, crosstalk, power delivery faults due to improper power supply decoupling and noise filtering, and power supply resonances.

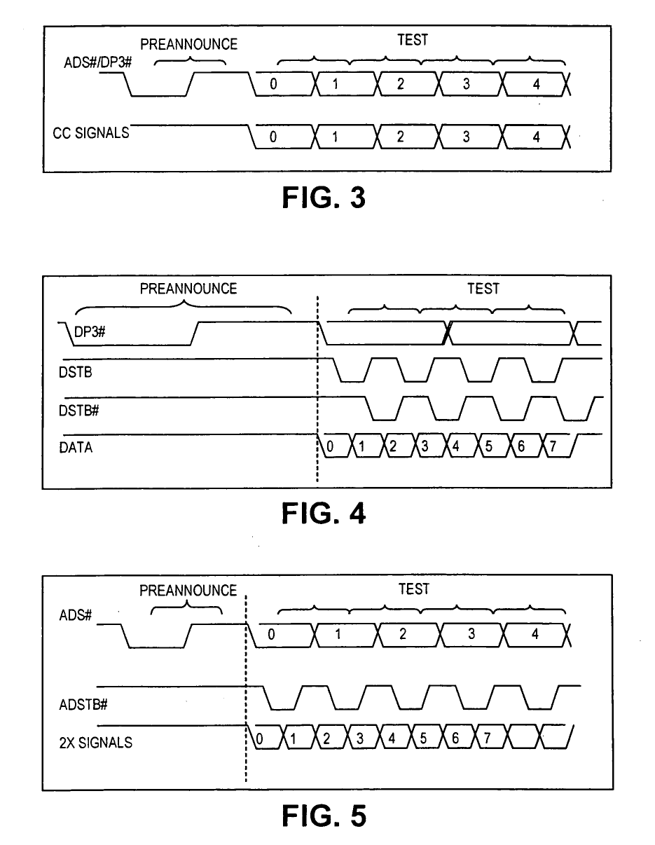

Each BIST unit 220 may be equipped with an IBIST cell 229 that is responsible for performing an interconnect test of a number of external pins of the component 208 and/or the bus 228. For example, the IBIST cells associated with two bus agents are first configured with the same test pattern. Next, a test session is started, by the master IBIST cell launching the test pattern, at the nominal bus speed, which is then captured by the slave IBIST cell and then compared to a copy of the pattern (that is stored in the slave cell). According to an embodiment of the invention, each IBIST cell is to recognize a start of the test session as being indicated by an assertion and deassertion, for predetermined time intervals, of a signal on the bus. Various examples of such a pre-announce signaling process are shown in FIGS. 3-5.

FIG. 3 is a conceptual timing diagram of an example pre-announce signaling process, for common clock signals. Note how the bus control signal ADS# (or DP3#) is asserted and then deasserted, before the test session actually begins with the launching of the test information elements via common clock (CC) signals. Both the master IBIST cell (which is driving the signals) and the slave IBIST cell have advance knowledge of the pre-announce features, including the relative order of the assertion and deassertion as well as their time intervals. In this case, each time interval is only one bus clock cycle, though shorter or longer time intervals (e.g. in multiples or fractions of a bus clock cycle) may alternatively be used. In some cases, the deassert interval should be long enough to allow sufficient time for all slave JBIST cells to respond and prepare for either driving or receiving test information elements at the start point of the test session.

Note also that, in FIG. 3, the test information elements are transmitted in a “common clock” signaling mode. Common clock signals are driven only once by a bus agent per bus clock cycle and are sampled based on the timing of the bus clock rather than specific strobe signals transmitted in conjunction with the signal being generated. The bus clock is typically generated by a clock chip or clock circuit provided on a motherboard, and is common to all processors or agents which communicate on the processor bus. Signal clocking with respect to the common bus clock, regardless of what internal signal(s) is/are used to approximate the bus clock, is referred to as common clock (1×) signaling mode. According to an embodiment, many control signals provided over the control bus are transmitted using the common clock (1×) signaling mode.

Turning now to FIG. 4, a conceptual timing diagram of another, example pre-announce signaling process is shown, this time for data pins of a parallel bus. This is an example of multi-pumped, source synchronous signaling. In a multi-pumped signaling mode, the information transfer rate is a multiple of the transfer rate supported by the common clock signaling mode. Thus, according to an embodiment, the multi-pumped signaling mode can support information transfer over the processor bus 117 between agents at a rate that is a multiple of the frequency of the common (i.e., system) bus clock. For example, the multi-pumped signaling mode may provide for example a double pumped signaling mode which allows information (e.g., data, addresses or other information) to be transferred at twice (2×) the rate of the common clock frequency, or may provide a quad pumped signaling mode which provides for information transfer at four times (4×) the bus clock frequency. To facilitate the transfer of information at such rates or frequencies which are greater than the common bus clock, the driving agent also issues or provides a companion strobe signal which is then used by the receiver as a reference for capturing or latching the multi-pumped information.

In FIG. 4, just as in FIG. 3, the pre-announce feature works by the assertion and deassertion of just one bus clock cycle in each case, immediately prior to the start of the test session. Again, the order of the assertion and deassertion, as well as their respective time intervals, may be changed to suit a given test scenario.

A conceptual timing diagram of another example, pre-announce signaling process, this time for address pins, is shown in FIG. 5. In this case, the test information is transmitted according to a double-pumped, source synchronous signaling methodology.

In the description above, it should be understood that a single test session may refer to multiple bus signal groups being tested simultaneously. In that case, the IBIST cells in a system may be configured to recognize each group (including perhaps a separate strobe signal associated with each group, if a source synchronous signaling mode is used) as having its own direction of test information flow. For example, a first IBIST cell may be configured to launch a first set of information elements via a first bus signal group at the start of the test session, for capture by a second IBIST cell. At the same time, the second IBIST cell will launch a second set of information elements via a second bus signal group, for capture by the first IBIST cell. One of these IBIST cells is designated the start master, to announce the start of the test session. One of the common clock signals of the bus may be “borrowed” by the start master, to use as a control signal for signaling the preannounce and start of the test session. Note also that in some embodiments, error information regarding the first bus signal group is generated and stored in the first IBIST cell (and retrieved via the TAP 240 of that cell), whereas errors regarding the second bus signal group are generated and stored in (and retrieved from) the second IBIST cell, and not the first.

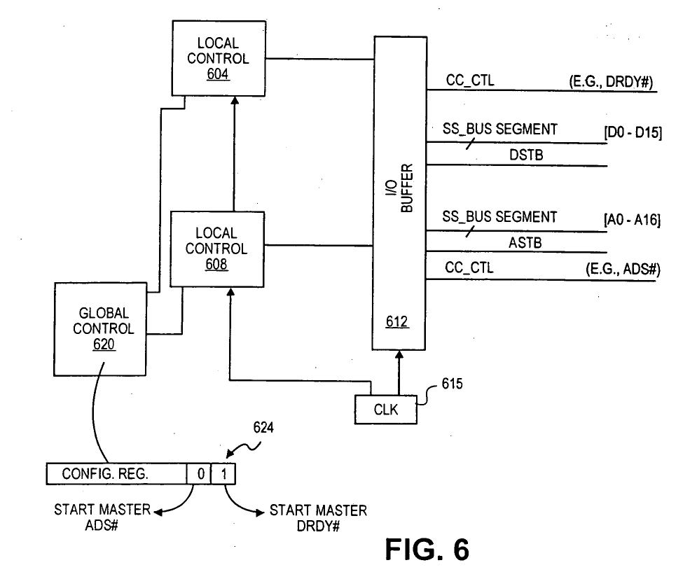

FIG. 6 is a logic block diagram of part of an IBIST cell with pre-announce signaling capability, for a parallel bus. There can be multiple local control blocks, such as blocks 604 and 608, each being responsible for launching and capturing test information elements on a separate bus signal group. In this example, both bus signal groups are source synchronous, one being data and the other address. The same I/O buffer circuitry 612 as used by the component's core function circuitry (not shown) is used by the local control blocks 604, 608. An internal clock circuit 615, which need not be derived from the bus clock or a strobe, may be used to provide a timing reference for the local control and I/O buffer circuitry, to launch the test patterns at the nominal bus speed.

A global control block 620 instructs the local control blocks 604, 608 as to whether they should be launching or capturing, during a given test session. A configuration register 624 (accessible via the test access port 240, see FIG. 2) allows the selection of a start master, together with the associated bus signal that will be asserted and deasserted, for the predetermined time intervals, to announce the start of a test session. In the example shown in FIG. 6, the start master is associated with the DRDY# signal, and not the ADS#. It should be noted that the configuration register in the other IBIST cells that will participate in the test session should not indicate the DRDY# signal as the start master.

The above described pre-announce capability may make it easier to design the logic circuitry of different IC components (e.g. a processor and a chipset), to be compatible for IBIST operations. In other words, it offers more flexibility in how to implement the IBIST logic, and alleviates timing constraints that are placed on the slave IBIST cell, in view of the timing requirements of the master IBIST cell. For example, instead of using a clock derived from a received bus strobe signal, a clock that is internal to the IC component, i.e. either on-chip or in-package, may be used for capturing a test pattern by a slave part of an IBIST cell of that component. That is because there is a clear beginning or start defined for the test session (by virtue of preannounce).

To summarize, various embodiments of a built-in self test methodology for computer systems have been described. In the foregoing specification, the invention has been described with reference to specific exemplary embodiments thereof. It will, however, be evident that various modifications and changes may be made thereto without departing from the broader spirit and scope of the invention as set forth in the appended claims. For example, the reference to a “computer system” is not intended to be limited to general purpose (e.g. personal) computers but rather encompasses any digital system board or platform that could benefit from the above described test methodology. In addition, the test methodology may be applied to test not only multi-drop buses but also the point-to-point variety. Also, although several different bus control signals have been identified above for carrying the preannounce feature, other types of inter-component signals can alternatively be used. These include signals that are used for communication between two or more IC components of a system, such as data signals, address signals, or a dedicated, preannounce signal. The specification and drawings are, accordingly, to be regarded in an illustrative rather than a restrictive sense.

What is claimed is:

1. A system comprising:
a carrier substrate;
a bus formed in the carrier substrate;
first and second agents on the bus to communicate with each other via respective I/O buffer circuitry at a nominal bus speed; and
first and second test units coupled to the bus to transfer test information between each other via said respective I/O buffer circuitry, at said nominal bus speed, and during a test session, wherein each test unit is to recognize a start of the test session as being indicated by an assertion and deassertion, for predetermined time intervals, of a signal on the bus.

2. The system of claim 1 wherein the bus is a point to point bus.

3. The system of claim 1 wherein the bus is a parallel bus and the carrier substrate is a printed wiring board, the system further comprising a third agent on the bus to communicate with the first and second agents via further I/O buffer circuitry, and a third test unit coupled to the bus to receive the test information via said further I/O buffer circuitry during the test session, and to recognize the start of the test session as being indicated by the assertion and deassertion, for predetermined time intervals, of the signal on the bus.

4. The system of claim 1 wherein said nominal bus speed is a bus clock frequency greater than 500 MHz.

5. The system of claim 3 wherein the first test unit is configured as a master to begin the test session by asserting and then deasserting the signal on the bus, and the second and third test units are configured as slaves for the test session and are to detect the assertion and deassertion of the signal.

6. The system of claim 4 wherein the test session refers to first and second bus signal groups, each group being associated with a separate, common clock, control signal,
the first test unit to launch a first set of information elements via the first bus signal group at the start of the test session, for capture by the second agent,
the second test unit to launch a second set of information elements via the second bus signal group at the start of the test session, for capture by the first agent.

7. The system of claim 1 wherein the control signal is a common clock signal being one of an address strobe signal and a data ready signal of a bus protocol used by the first and second bus agents to one of request a transaction and signal the availability of response data, respectively.

8. The system of claim 1 wherein the predetermined time interval during which the signal is to be asserted is one bus clock cycle long, and the predetermined time interval during which the signal is to be deasserted is one bus clock cycle long.

9. The system of claim 8 wherein the predetermined time interval during which the signal is to be asserted or deasserted is just one bus clock cycle long.

10. The system of claim 8 wherein the bus is a parallel bus, the carrier is a printed wiring board, the first agent is a processor, the second agent is a system chipset, and the system is a high volume manufacturing specimen.

11. A method comprising:
signaling, by a built-in test unit of a first primary integrated circuit (IC) component of a computer system having a processor, a system interface, and main memory, the start of a test session by asserting and deasserting, for predetermined time intervals, a signal on a bus of the system;
recognizing, by a built-in test unit of a second primary IC component of the system, the start of the test session by detecting said assertion and deassertion of the signal; and
transferring test information between said primary components on the parallel bus, at a nominal bus speed, during the test session.

12. The method of claim 11 further comprising:
recognizing, by a built-in test unit of a third primary IC component of the system, the start of the test session by detecting said assertion and deassertion of the signal.

13. The method of claim 12 wherein the test unit of the first component has been designated as a master to announce the test session by asserting and then deasserting the signal on the bus, and the test units of the second and third components have been designated as slaves for the test session.

14. The method of claim 11 wherein the test session is to test first and second source synchronous bus signal groups,
the test unit of the first component to launch a first set of information elements on the first bus signal group at the start of the test session, for capture by the second component,
the test unit of the second component to launch a second set of information elements on the second bus signal group at the start of the test session, for capture by the first component.

15. The method of claim 11 wherein the signal is a bus control signal that is also used by core function circuitry of the first component for bus communications.

16. The method of claim 11 wherein the predetermined time interval during which the signal is asserted is one bus clock cycle long, and the predetermined time interval during which the signal is deasserted is also one bus clock cycle long.

17. An article of manufacture comprising:
an integrated circuit (IC) component of a computer system, the component being intended for use as part of a production version of the system, the component having a built-in test unit and core function circuitry that are coupled to transfer information over the same I/O buffer circuitry of the component, the test unit to transfer test information during a test session and to recognize announcement of the test session via an assertion and a deassertion, for predetermined time intervals, of an inter-component signal.

18. The article of claim 17 wherein the test unit is designed to recognize said predetermined time intervals as being independent of a bus protocol that is to be used by the core function circuitry during normal operation of the system.

19. The article of claim 17 wherein the test unit is to be one of (a) a test master to announce the test session by asserting and then deasserting the signal, and (b) a test slave to monitor the signal for announcement of the test session.

20. The article of claim 19 wherein the test unit is to launch, at a nominal bus speed, a first set of information elements on a first bus signal group and capture a second set of information elements on a second bus signal group according to different common clock control signals, at the start of the test session.

21. The article of claim 17 wherein the control signal is one of an address strobe signal and a data ready signal that is also used by the core function circuitry to one of request a transaction and signal the availability of response data, respectively.

22. The article of claim 17 wherein the test unit understands the predetermined time interval during which the signal is to be asserted as being one bus clock cycle long, and the predetermined time interval during which the signal is to be deasserted is also one bus clock cycle long and immediately follows the assertion.

23. The article of claim 22 wherein the predetermined time interval during which the signal is asserted or deasserted is only one bus clock cycle long.

24. The article of claim 23 wherein the component is one of a processor and a system chipset.
